(19) United States
(12) Patent Application Publication
(10) Pub. No.: US 2007/0153490 A1
(43) Pub. Date: Jul. 5, 2007

(54) Methods and apparatus for electromagnetically sampling signals using socket-package interface based interposer

(76) Inventor: John R. Benham, Hopkinton, MA (US)

Correspondence Address: BUCKLEY, MASCHOFF & TALWALKAR LLC, 50 LOCUST AVENUE, NEW CANAAN, CT, 06840, US

(21) Appl. No.: 11/322,909

(22) Filed: Dec. 30, 2005

(51) Int. Cl. H05K 7/00

(52) U.S. Cl. 361/777

(57) ABSTRACT

An article of manufacture includes a substrate and a first electrical conductor supported on the substrate. The first electrical conductor is to carry a signal from an integrated circuit package. In addition, the article of manufacture includes a second electrical conductor supported on the substrate and located to electromagnetically couple to the first electrical conductor. The second electrical conductor is to be coupled to a signal analyzer.

### BACKGROUND

As bus signal data rates reach microwave frequencies, it becomes increasingly difficult to monitor the logic states of the signals using resistive coupling to a logic analyzer without excessively perturbing the signals being observed. It may therefore be advantageous to employ electromagnetic coupling to sample bus signals since electromagnetic coupling has little impact on the signals being observed. However, there are practical difficulties involved with electromagnetic coupling related to the necessary length of the coupling structure. Coupling is most efficient at frequencies where the coupled electrical length of the conductors is close to λ4, where λ is the wavelength. For data rates in the range of about 2-10 Gb/s, it may be desirable to have a coupled length of about 100-160 mils in motherboard traces to provide sufficient output pulse amplitude and energy content for satisfactory analysis. However, the small physical volume available for a typical socket geometry may not readily accommodate a coupler of the desired length.

### BRIEF DESCRIPTION OF THE DRAWINGS

FIG. 1 is a schematic side cross-sectional view of a test set-up according to some embodiments.

FIG. 2 is a partial schematic isometric view showing a coupler that may be used in the test set-up of FIG. 1.

FIG. 3 is a schematic vertical cross-sectional view of the coupler of FIG. 2.

FIG. 4 is a partial schematic isometric view showing another coupler that may be used in the test set-up of FIG. 1.

FIG. 5 is a schematic vertical cross-sectional view of the coupler of FIG. 4.

FIG. 6 is a partial schematic isometric view showing still another coupler that may be used in the test set-up of FIG. 1.

FIG. 7 is a partial schematic isometric view showing yet another coupler that may be used in the test set-up of FIG. 1.

### DETAILED DESCRIPTION

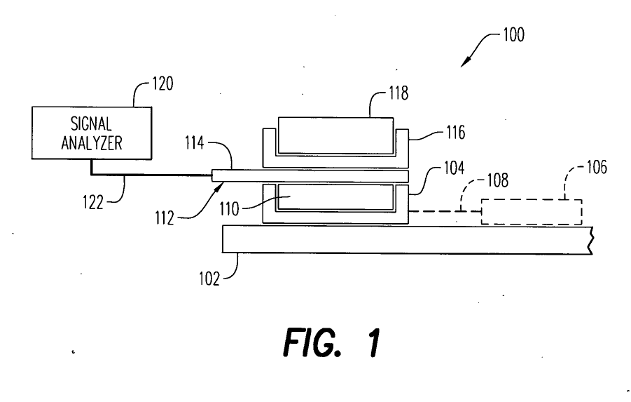

FIG. 1 is a schematic side cross-sectional view of a test set-up 100 according to some embodiments. The test set-up 100 includes a circuit board 102 having a socket 104 mounted thereon. The circuit board 102 also has various system components (indicated schematically at 106) such as one or more memory devices, a chipset, etc. Dashed line 108 represents signal connections between the socket 104 and the other system components 106, although it will be understood that in practice that the signal connections may be provided as signal traces on or in the circuit board 102. The circuit board 102, the socket 104, the other system components 106 and the signal connections 108 may all be provided in accordance with conventional practices.

The test set-up 100 also includes a spacer 110 installed in the socket 104. The spacer is structured to provide signal connections (not separately shown) from the floor of the socket 104 to a level even with the top of the socket 104.

The test set-up 100 further includes an interposer card 112 that is mounted on the spacer 110 and electrically coupled to the socket 104 via the spacer 110. The interposer card 112 includes a card body 114 and a socket 116 mounted on the card body 114. Details of various embodiments of the card body 114 will be described below.

The test set-up 100 further includes an integrated circuit (IC) package 118 installed in the socket 116 of the interposer card. The IC package 118 may be constructed in accordance with conventional practices and may comprise, for example, a conventional microprocessor (not separately shown). In addition, the test set-up includes a signal analyzer 120 (e.g., a logic analyzer) which is coupled via a signal path 122 to the interposer card 112. The signal analyzer 120 may be provided in accordance with conventional practices. In some embodiments, a receiver (not shown) may be in the signal path 122 to integrate the signal to be provided to the signal analyzer 120. The integrating receiver may be needed since a coupler (to be described below) on the interposer card 112 may effectively differentiate a signal to be observed by the signal analyzer 120.

The sockets 104, 116 may be of substantially the same configuration such that both of the sockets are suitable for receiving the IC package 118. However, in other embodiments, the sockets 104, 116 may have different configurations.

The microprocessor or other IC included in the IC package 118 may be in communication with at least some of the other system components 106 via the socket 116, the interposer card body 114, the spacer 110, the socket 104 and the signal connection(s) 108. The card body 114 may include one or more couplers (not separately shown in FIG. 1) according to one or more of the embodiments described below, to pick up signals passing from or to the IC package 118. The signals picked up by the coupler(s) are provided to the signal analyzer 120 to be analyzed by the signal analyzer.

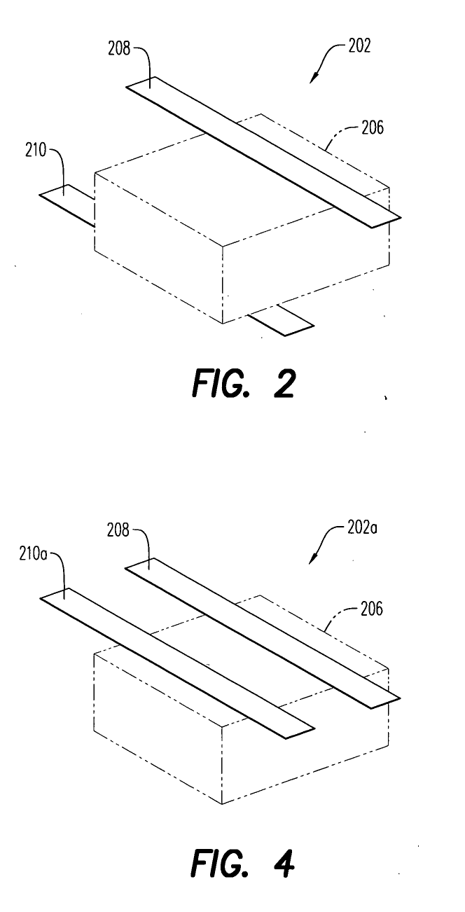

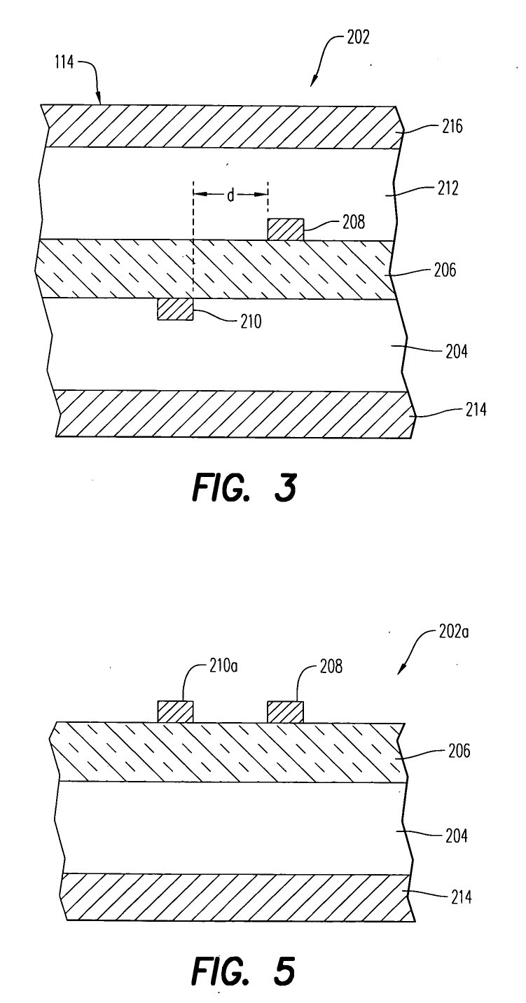

FIG. 2 is a partial schematic isometric view showing a coupler 202 which is formed as part of the card body 114 of the interposer card 122 and thus is part of the test set-up 100. FIG. 3 is a schematic vertical cross-sectional view of the coupler 202. Referring primarily to FIG. 3, the card body 114 includes a substrate 204, which may be formed of a material from which circuit boards are customarily made. For example, the material may be the well-known composite material referred to as FR4. Nelco 4000-13 is another suitable material for the substrate. At least in the region of the coupler 202, another material 206 is present on the top surface of the substrate 204. As is well-known, FR4 has a dielectric coefficient of about 4. To increase the effective length of the coupler, the material 206 may have a substantially higher dielectric constant. For example, the material 206 may be “NanoEC”, available from PPL, Albuquerque, N. Mex. NanoEC has a dielectric constant of about 20. Other materials having a relatively high dielectric constant as compared to FR4 may also be used. For example, materials known as Rogers RO3210 or Dupont EP 310 may be suitable. Materials based on nano-particles may also be used.

The coupler 202 also includes an electrical conductor 208 which may be a signal trace (e.g., a copper trace) that forms part of the connection to carry a signal from the IC package 118 to the socket 104. The conductor 208 is in contact with a top surface of the material 206. In addition, the coupler 202 includes an electrical conductor 210, which may also be formed as a copper trace. The conductor 210 is in contact with a bottom surface of the material 206 and is coupled electromagnetically to the conductor 208 via the material 206. The conductor 210 is coupled to the signal analyzer 120 (FIG. 1) via the signal path 122 and serves as a pickup for the signal from the IC package 118 that is to be analyzed by the signal analyzer 120. The conductor 210 may (but need not) be laterally offset from the conductor 208, as illustrated in FIGS. 2 and 3. For example, the distance “d” shown in FIG. 3, by which the conductor 210 is offset laterally from the conductor 208, may be selected to control the coupling coefficient value for the coupler 202. Conversely, lateral offsets such as “d” in FIG. 3 may arise from errors in the conductor positioning during manufacture and it may be necessary to select the shape of the conductors in the horizontal plane to minimize the variation in coupling coefficient that such positional variation would otherwise produce.

To describe further aspects of the coupler 202 or of the card body 114 in which the coupler 202 is formed, and referring once more to FIG. 3, another dielectric layer 212 which may be of the same material as the substrate 204 (or of a different material) may be provided on top of the material 206. For example, the structure formed of the substrate 204 and the material layers 206 and 212 may be formed by laminating the substrate 204 and the material layer 212 together with the material 206 squeezed between the substrate 204 and the material layer. In addition, a ground plane 214 (e.g., of copper) is below the substrate 204 and another ground plane 216 (which may also be of copper) is above the material layer 212, to form a so-called microstrip structure with respect to the coupler 202. The structure shown in FIG. 3 may include other layers, which are not shown, such as layers to cover the ground planes. It is also possible to fabricate the layers 204 and 212 from two or more separate layers of material of differing dielectric constants in order to modify the effective dielectric constant of the layers 204, 212.

FIG. 4 is a partial schematic isometric view showing a coupler 202a which may be formed as an alternative to the coupler 202 shown in FIGS. 2 and 3. The coupler 202a may be formed as part of the card body 114 of the interposer card 122. FIG. 5 is a schematic vertical cross-sectional view of the coupler 202a. The coupler 202a may have the same substrate 204, material 206, signal line conductor 208 and ground plane 214 as in the coupler 202. In place of the coupled pickup conductor 210 shown in FIGS. 2 and 3, the coupler 202a may have a coupled pickup conductor 210a which is in contact with the same surface of the material 206 as the conductor 208.

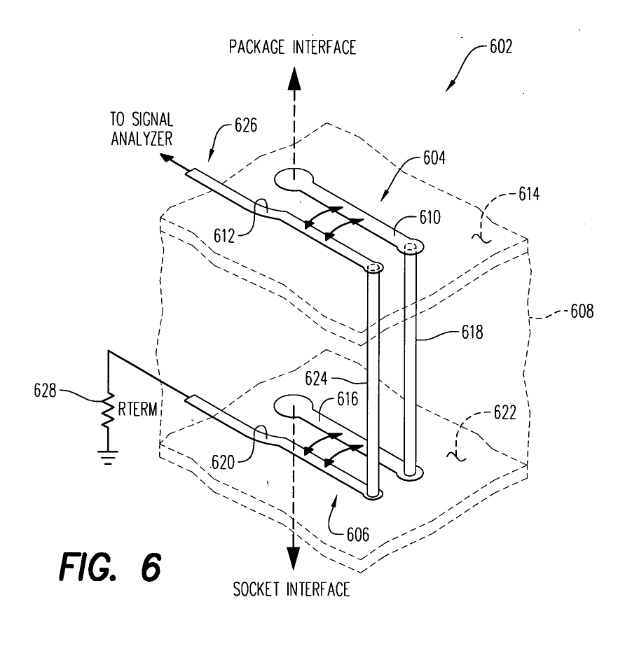

FIG. 6 is a partial schematic isometric view showing still another coupler (generally indicated by reference numeral 602) that may be used in the test set-up 100 as an alternative to the coupler 202 described above. The coupler 602 is formed as part of the interposer card 112 (FIG. 1) and includes an upper leg 604 and a lower leg 606, which are on opposite sides of a substrate 608 from each other. The substrate 608 may be formed of FR4 or another material conventionally used for circuit board cores.

The upper leg 604 of the coupler 602 may include a signal line conductor 610 (which as before may be formed as a copper trace) which is part of the signal line from the IC package 118 (FIG. 1) to the socket 104. The upper leg 604 of the coupler 602 may also include a coupling conductor 612 which is adjacent to the conductor 610 and is electromagnetically coupled to the conductor 612 via a patch 614 of a relatively high dielectric constant material on the substrate 608. The material of patch 614 may be of the same type discussed in connection with the material 206 of the couplers 202, 202a. In some embodiments, as shown in FIG. 6, the conductors 610, 612 may be formed as parallel adjacent traces both in contact with the patch 614.

The lower leg 606 of the coupler 602 may include a signal line conductor 616 (again a copper trace, for example), which is part of the signal line and is directly connected to the conductor 610 by a microvia 618. The lower leg 606 of the coupler 601 may also include a coupling conductor 620 which is adjacent to the conductor 616 and is electromagnetically coupled to the conductor 616 via a patch 622 formed of the same material as patch 614 and on the underside of the substrate 608. The coupling conductor 620 of the lower leg 606 is directly connected to the coupling conductor 620 of the upper leg 604 by a micro via 624. The coupling conductors 612, 620 may, as indicated at 626 in FIG. 6, be coupled to the signal analyzer 120 (FIG. 1, not shown in FIG. 6), by, e.g., signal path 122 (FIG. 1). In addition, the coupling conductors 612, 620 may be connected to ground via a terminating resistor schematically indicated at 628.

With the two legs of the coupler 602, on opposite sides of the substrate, the effective length of the coupler is increased. Also, as in the previous embodiments, the effective length of the coupler may be further increased by the presence of the high dielectric constant material in contact with the coupled conductors. The conductors may be placed on the same side of the high dielectric material using coupling between the conductor edges, or they may be placed on opposite sides of the material to utilize broadside coupling.

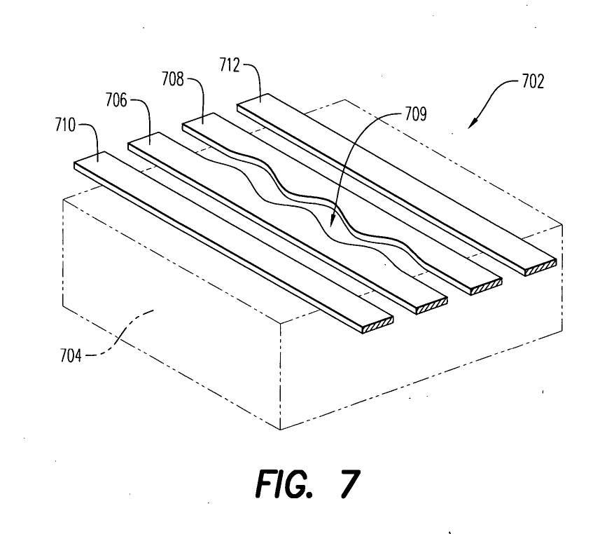

FIG. 7 is a partial schematic isometric view showing yet another embodiment of a coupler (generally indicated by reference numeral 702) that may be incorporated in the interposer card 112 (FIG. 1) in the test set-up 100. The coupler 702 is suitable for picking up a differential signal from the IC package 118 (FIG. 1)

Referring to FIG. 7, the coupler 702 includes a patch 704 of a material (such as, e.g., the material 206 discussed above) having a relatively high dielectric constant. The patch 704 may be on a substrate (not shown) made of FR4 or other conventional circuit board core material. The coupler 702 also includes a pair of differential signal lines (conductors) 706, 708 which form part of the signal path from the IC package 118 (FIG. 1) to the socket 104. The conductors 706 and 708 are adjacent to each other and have mutually facing sides that are meandered (as indicated at 709) in a complementary fashion. The conductors 706, 708 are in contact with the patch 702 of high dielectric constant material.

In addition, the coupler 702 includes a pickup conductor 710 that is adjacent the signal line conductor 706 on the opposite side from the signal line conductor 708, and a pickup conductor 712 that is adjacent the signal line conductor 708 on the opposite side from the signal line conductor 706. The conductors 710, 712 are in contact with the patch 702 of high dielectric constant material. The conductor 710 is electromagnetically coupled via the patch 702 to the conductor 706. The conductor 712 is electromagnetically coupled via the patch 702 to the conductor 708. The conductors 710, 712 may be coupled to the signal analyzer 120 (FIG. 1) via the signal path 122.

All of the conductors 706, 708, 710, 712 may be formed as copper traces, for example.

The meandering of the inner faces of the conductors 706, 708 introduces a longer path length for the differential electromagnetic field mode, to allow for adjustment of the relative odd and even mode propagation velocities for the signal pair 706, 708 independent of the modal velocities of the coupled pairs 706, 710 and 708, 712. This may allow for some compensation for the modal propagation velocity disparity produced by the presence of the high dielectric constant patch 702. Consequently, the differential pair reflection seen by the signal pair 706, 708 may be minimized. Although not shown in the drawing, the interfaces between the conductors 706, 710 and between conductors 708, 712 may also be meandered to provide improvement in the coupled pair differential coupling coefficients.

In embodiments described above, coupling to the signal line in the interposer card may be via a relatively high dielectric material. Alternatively, the high dielectric material may be omitted.

The several embodiments described herein are solely for the purpose of illustration. The various features described herein need not all be used together, and any one or more of those features may be incorporated in a single embodiment. Therefore, persons skilled in the art will recognize from this description that other embodiments may be practiced with various modifications and alterations.

What is claimed is:

1. An article of manufacture, comprising:
a substrate;
a first electrical conductor supported on the substrate, said first electrical conductor to carry a signal from an integrated circuit package; and
a second electrical conductor supported on the substrate and located to electromagnetically couple to said first electrical conductor, said second electrical conductor to be coupled to a signal analyzer.

2. The article of manufacture of claim 1, wherein the substrate is formed of a first material having a first dielectric constant, the article of manufacture further comprising a second material on the substrate, the second material having a second dielectric constant that is higher than the first dielectric constant, the first and second electrical conductors in contact with the second material.

3. The article of manufacture of claim 2, wherein said second dielectric constant is at least four times said first dielectric constant.

4. The article of manufacture of claim 2, wherein:
said first electrical conductor is in contact with a first surface of said second material; and
said second electrical conductor is in contact with said first surface of said second material.

5. The article of manufacture of claim 2, wherein:
said first electrical conductor is in contact with a first surface of said second material; and
said second electrical conductor is in contact with a second surface of said second material that is opposite said first surface of said second material.

6. The article of manufacture of claim 2, wherein the first and second electrical conductors are copper traces.

7. The article of manufacture of claim 2, further comprising:
a third electrical conductor in contact with said second material and adjacent said first electrical conductor to carry said signal from said integrated circuit package; and
a fourth electrical conductor in contact with said second material and located to electromagnetically couple to said third electrical conductor, said fourth electrical conductor to be coupled to said signal analyzer.

8. An apparatus comprising:
a circuit board;
a first socket mounted on the circuit board;
a spacer installed in the first socket;
an interposer card electrically coupled to the first socket via the spacer;
a second socket mounted on the interposer card; and
an integrated circuit (IC) package installed in the second socket.

9. The apparatus of claim 8, further comprising:
a signal analyzer;
and wherein said interposer card includes:
a substrate;
a first electrical conductor supported on the substrate said first electrical conductor to carry a signal from said IC package; and
a second electrical conductor supported on the substrate and located to electromagnetically couple to said first electrical conductor, said second electrical conductor coupled to said signal analyzer.

10. The apparatus of claim 9, wherein the substrate is formed of a first material having a first dielectric constant, the interposer card further comprising a second material on the substrate, the second material having a second dielectric constant that is higher than the first dielectric constant, the first and second electrical conductors in contact with the second material.

11. The apparatus of claim 10, wherein said second dielectric constant is at least four times said first dielectric constant.

12. The apparatus of claim 10, wherein:
said first electrical conductor is in contact with a first surface of said second material; and
said second electrical conductor is in contact with said first surface of said second material.

13. The apparatus of claim 10, wherein:
said first electrical conductor is in contact with a first surface of said second material; and
said second electrical conductor is in contact with a second surface of said second material that is opposite said first surface of said second material.

14. The apparatus of claim 10, wherein the first and second electrical conductors are copper traces.

15. The apparatus of claim 8, wherein the first and second sockets are of substantially the same configuration.

16. A method comprising:
providing on a substrate a first electrical conductor and a second electrical conductor; and
analyzing a signal electromagnetically coupled to said second electrical conductor from said first electrical conductor.

17. The method of claim 16, wherein the substrate is formed of a first material having a first dielectric constant, and the first and second electrical conductors are in contact with a second material on the substrate, the second material having a second dielectric constant higher than the first dielectric constant.

18. The method of claim 17, further comprising:
coupling said first electrical conductor to an integrated circuit package; and
coupling said second electrical conductor to a signal analyzer.

19. The method of claim 17, wherein said second dielectric constant is at least four times said first dielectric constant.

20. The method of claim 17, wherein:
said first electrical conductor is in contact with a first surface of said second material; and
said second electrical conductor is in contact with said first surface of said second material.

21. The method of claim 17, wherein:
said first electrical conductor is in contact with a first surface of said second material; and
said second electrical conductor is in contact with a second surface of said second material that is opposite said first surface of said second material.
